(19) United States
(12) Patent Application Publication
(10) Pub. No.: US 2026/0176191 A1
(43) Pub. Date: Jun. 25, 2026

(54) HOT END METAL OXIDE COATINGS FOR GLASS SUBSTRATES AND CONTAINERS

(71) Applicant: Arkema Inc., King of Prussia, PA (US)

(72) Inventors: Sandrine Nathalie RIVILLON, King of Prussia, PA (US); Marina DESPOTOPOULOU, King of Prussia, PA (US); Ryan Christopher SMITH, King of Prussia, PA (US); Leonard H. PALYS, King of Prussia, PA (US)

(21) Appl. No.: 19/126,288

(22) PCT Filed: Oct. 26, 2023
(86) PCT No.: PCT/US2023/077882

§ 371 Date: May 1, 2025

Related U.S. Application Data
(60) Provisional application No. 63/421,279, filed on Nov. 1, 2022.

(51) Int. Cl. C03C 17/00; C03C 17/36; C03C 17/42; C23C 16/40

(52) U.S. Cl. CPC C03C 17/005; C03C 17/3618; C03C 17/3626; C03C 17/3644; C03C 17/3681; C03C 17/42; C23C 16/40; C03C 2217/475; C03C 2218/114; C03C 2218/153

(57) ABSTRACT

A method of coating a glass substrate with a hot end coating is provided. The method comprises a step of applying an aqueous dispersion including particles of a metal hydroxide composition onto a surface of the glass substrate to form a hot end coating on the glass substrate. The glass surface has a temperature of from about 450° C. to about 1000° C. when the aqueous dispersion is applied thereto. After application, the hot end coating includes oxide(s) of the metal or combinations thereof. A coated glass article is also provided. The coating on the glass article includes at least one of Group 3 A oxides, Group 4A oxides, or combinations thereof; preferably TiO₂, TiO, Ti₂O₃, Ti_{z}Oₐ (0<z≤2 and 0<a≤3), ZrO₂, Z_{rb}Oc (0<b≤1 and 0<c≤2), Al₂O₃, Al₂O, AlO, AlₓO_{y} (0<x≤2 and 0<y≤3) or combinations thereof; more preferably Al₂O₃, Al₂O, AlO, AlₓO_{y} (0<x≤2 and 0<y≤3) or combinations thereof.

### FIELD OF THE INVENTION

The invention relates to hot end metal oxide coatings for glass articles and substrates, such as containers, bottles, and flat glass, methods of applying hot end metal oxide coatings during the manufacture of glass articles and substrates, and to glass articles and substrates coated with such coatings.

### BACKGROUND

Glass articles, especially glass containers and bottles, typically require coatings applied to the surface thereof. The coatings impart desirable properties, such as improved adherence to further coatings which provide additional desirable properties such as scratch protection and durability. Glass containers, especially glass bottles, may be made by a number of methods, but they typically all have in common the following steps:
1. Melting sand with modifiers at temperature above 1200° C. to eventually generate a gob;
2. Forming the hot gob into a container;
3. Optionally, coating the hot container with a coating. This coating, if applied, is referred to as a “hot end” coating. The hot end coatings will protect the glass and may act as a primer to any optional additional coating while at the same time having suitable optical properties so that the resulting container remains clear and lacks iridescence. Hot end coatings also provide a surface that can adhere to any coatings applied later in the process, such as cold end coatings and/or labels or other markings;
4. Cooling the hot container. The cooling is done under controlled conditions because cooling the formed container too fast can cause the container to shatter; and
5. Optionally, applying a coating to the cooled glass container. This coating, if applied, is referred to as a “cold end” coating and typically comprises a wax. These cold end coatings may impart properties such as improved lubricity (e.g. for easier automated handling), scratch resistance, improved durability and strength, and/or improved adherence of labels.

It is desirable to increase the efficiency and safety of the hot end coating process. Currently, some hot end precursors such as monobutyltin trichloride, tin tetrachloride or titanium isopropoxide are applied to the hot glass substrate using a chemical vapor deposition method. In chemical vapor deposition, the material to be used as the coating is vaporized, typically by vaporization of a liquid, usually at an elevated temperature and atmospheric pressure. The vapor deposits on and/or reacts with the hot glass surface. Such a coating (hot end coating) will protect the glass container and is used as a primer for the subsequent deposition of a cold end coating which adheres to the metal oxide surface and protects the glass from scratches and helps to preserve the glass strength. Tin precursors are strongly acidic and the release of HCl from the CVD reaction will corrode the coating equipment used to apply them. An alternative to conventional tin precursors, such as titanium isopropoxide, is flammable and may be hazardous to health. During the CVD process, the build-up on the coating equipment may occur over time leading to stoppage of the process in order to perform regular maintenance of the equipment and cleaning which is inefficient and costly.

Other coating methods have been described in EP 3 024 792; WO 2012/053919; and in Processing, Properties, and Applications of Glass and Optical Materials: Ceramic Transactions; Edited by Arun K. Varshneya, Helmut A. Schaeffer, Kathleen A. Richardson, Marlene Wightman and L. David Pye; (2012). The aforementioned publications disclose a method of applying powder of Al(OH)₃ onto hot and/or cold glass containers to form a coating. There is described a process where, in order to be able to apply the nanopowder on the glass, the initial material is dry ground by using a mill that could easily contaminate the powder and in turn the resulting coating. In addition, applying a powered coating onto a hot glass surface has undesirable environmental and safety limitations, due to the necessity of containing the powder.

WO 2006/060510 describes an alumina dispersion.

Therefore, a need exists for a method of applying a hot end coating to a glass substrate which is non-corrosive, non-hazardous, provides little to no hazardous emissions, and that avoids build-up on the equipment, while at the same time being efficient, cost effective, safe, environmentally friendly, and which achieves the desirable properties and characteristics of a hot end coating such as being substantially transparent, substantially colorless, and without iridescence.

### SUMMARY

The inventors have surprisingly found that an ambient temperature aqueous dispersion comprising solid particles of a metal hydroxide composition may be applied directly onto a hot surface of a glass substrate thereby forming a suitable hot end coating. The surface of the glass substrate may have a temperature of from about 450° C. to about 1000° C. The inventors also discovered that spraying the aqueous dispersion is a suitable method for applying a coating onto the heated surface. Upon spraying the aqueous dispersion onto the hot glass, a coating comprising oxides of the metal(s) is formed on the glass substrate. The deposited metal oxide coating is substantially transparent or transparent, substantially colorless or colorless, and/or substantially without iridescence or without iridescence to the naked eye. After a hot end coating according to the invention has been applied to a glass surface, optionally an additional cold end coating, preferably in the form of a polymer formulation, can be deposited onto the hot end coating and adhered thereto.

Accordingly, a method of coating a glass substrate with a coating is provided. This coating is a hot end coating. The coating is inorganic. The method comprises the following steps:

a) Applying an aqueous dispersion comprising particles of metal hydroxide composition onto a surface of the glass substrate, the surface having a temperature of from about 450° C. to about 800° C., thereby forming a hot end coating on the glass substrate. In various embodiments, the surface has a temperature of from 450° C. to 1000° C. before, when first applied, or after, application of the aqueous dispersion. After application of the aqueous dispersion, the hot end coating comprises oxide(s) of the metal, or combinations thereof.

A coated glass article is also provided. The article comprises a glass substrate and a hot end coating on the glass substrate. The coating comprises at least one of Group 3A oxide(s), Group 4A oxide(s), or combinations thereof; preferably TiO₂, TiO, Ti₂O₃, Ti_{z}Oₐ (0<z≤2 and 0<a≤3) ZrO₂, Zn_{b}O_{c} (0<b≤1 and 0<c≤2) Al₂O₃, Al₂O, AlO, AlₓO_{y} (0<x≤2 and 0<y≤3) or combinations thereof; more preferably Al₂O₃, Al₂O, AlO, AlₓO_{y} (0<x≤2 and 0<y≤3) or combinations thereof.

### BRIEF DESCRIPTION OF THE DRAWINGS

FIG. 1 shows a scanning electron microscope (SEM) image taken at 50× of an aluminum oxide hot end coating sample on soda lime glass according to an embodiment of the invention. The aqueous dispersion was sprayed at 15 psi.

FIG. 2 shows an SEM image taken at 50× of a different aluminum oxide hot end coating sample on soda lime glass according to an embodiment of the invention. The aqueous dispersion was sprayed at 15 psi.

FIG. 3 shows an SEM image taken at 50× of the same aluminum oxide hot end coating sample shown in FIG. 2 on soda lime glass according to another embodiment of the invention. The aqueous dispersion was sprayed at 30 psi.

### DETAILED DESCRIPTION

A method of coating a glass substrate with a coating is provided. The coating is a “hot end” coating to which a “cold end” coating may optionally be applied.

The method comprises the following step:
a) applying an aqueous dispersion comprising particles of a metal hydroxide composition onto a surface of the glass substrate, the surface having a temperature of from about 450° C. to about 1000° C., thereby forming a hot end coating on the glass substrate. After application of the aqueous dispersion, the hot end coating comprises oxide(s) of the metal, or combinations thereof.

According to an embodiment, the method may further comprise the following steps:
b) optionally cooling the glass substrate and the hot end coating to a temperature of from about 80° C. to about 350° C., preferably from about 100° C. to about 250° C., more preferably from about 100° C. to about 200° C.; and
c) optionally applying a cold end coating onto the hot end coating.

According to another embodiment, the aqueous dispersion is applied by spraying. The spraying may be done using a sprayer equipped with a nozzle through which the aqueous dispersion will be atomized at a pressure from about 2 to about 100 psi, preferably at a pressure from about 2 to about 70 psi. The type of sprayer is not particularly limited, but for example, may use a compressed gas, such as nitrogen, or oxygen, or air as a propellant. The sprayer may be of the airless type, in which case the aqueous dispersion is pressurized and no propellant is used. Non-limiting examples of sprayers that may be used are hydraulic, pneumatic, or mechanical atomizers, or combinations thereof. Other non-limiting examples of sprayers that may be used are an ultrasonic atomizer, rotary atomizer, airless atomizer, or electrostatic atomizer, and such sprayers also may be characterized by nozzle and orifice geometry and configuration, spray patterns, droplet size and droplet size distribution which they may produce. Several such technologies are discussed in “Atomization and Sprays,” 2nd Edition, by Arthur Lefebvre and Vincent McDonell (CRC Press, 2017) and “Classification of Atomization Devices”, by A. Yu Vasilyev, E. S. Domrina, S. V. Kaufman, and A. I. Maiorova (Journal of Physics: Conference Series 1359 (2019) 012131), the contents of which are incorporated herein.

The aqueous dispersion may have a viscosity from about 1×10⁻⁵ Pa·s to about 100,000 Pa·s, preferably from about 1×10⁻⁴ to about 10,000 Pa·s, and more preferably from about 1×10⁻⁴ to about 1,000 Pa·s, measured at 25° C. at a shear rate of 0.1 s⁻¹. The aqueous dispersions may be newtonian or non-newtonian fluids.

According to an embodiment, the application of the aqueous dispersion of the metal hydroxide composition on to the surface of the hot glass substrate is performed in air and at atmospheric pressure. This atmospheric pressure refers to the pressure surrounding the hot glass substrate, not the pressure that may be used to spray the aqueous dispersion of the metal hydroxide composition.

### Glass Substrate:

Non-limiting examples of suitable glass substrate may be silicate glass, quartz glass, borosilicate glass, soda lime glass, crystal glass, aluminosilicate glass, germanium silicate glass, phosphosilicate glass, or crown glass. The glass substrate may comprise from 1 to 100 wt % SiO₂. The glass substrate may comprise other elements such as sodium, calcium, aluminum, iron, magnesium, boron, lead, sulfur, carbon, selenium, chromium, cobalt, nickel, manganese, phosphorus, germanium, and/or potassium. The glass substrate may comprise from 0 to 100 wt % recycled glass.

### Aqueous Dispersion

The aqueous dispersion comprises (solid) particles of a metal hydroxide composition. The particles may have a volumetric average particle size of from about 1 nm to about 100 microns or from about 1 nm to about 50 microns, or from about 1 nm to about 25 microns, or from about 1 nm to about 10 microns, or from about 1 nm to about 5 microns as measured by X-ray diffraction or light scattering. The appropriate measurement technique depends on the particle size. The particle size range may be monomodal or bimodal or multimodal, for example.

As noted above, when sprayed onto the surface of the glass substrate, the aqueous dispersion may have a temperature of from about 10° C. to about 70° C., from about 15° C. to about 60° C., preferably from about 20° C. to about 50° C. Surprisingly, in view of the large difference between the temperature of the aqueous dispersion and the surface of the glass substrate, the glass substrate does not shatter or weaken upon application of the (relatively) cool aqueous dispersion. The aqueous dispersion may have a pH of less than about 8, preferably from about 1 to about 7, more preferably from about 2 to about 7, most preferably from about 3 to about 7.

The aqueous dispersion may further comprise at least one acid, preferably a mineral acid, or combination thereof. Suitable acids preferably comprise at least one of nitric acid, acetic acid, formic acid, hydrochloric acid, sulfuric acid, phosphoric acid, hydrobromic acid, or combinations thereof. The acid may more preferably comprise nitric acid, formic acid, or a combination thereof. The acid may most preferably comprise nitric acid. The acid or combination of acids is added in an amount to achieve the desired pH of the aqueous dispersion that is applied to the surface of the glass substrate to form the hot end coating. According to an embodiment, deionized water may used to form the aqueous dispersion. According to an embodiment, tap water may be used to form the aqueous dispersion.

The aqueous dispersion may comprise about 1 to about 70 wt %, preferably about 2 to about 70 wt %, more preferably about 5 to 70 wt %, most preferably about 10 to about 70 wt % of the solid particles of the metal hydroxide composition by weight of the aqueous dispersion.

The dispersion may further comprise at least one salt, preferably at least one salt comprising at least one of Group 3A or Group 4 elements or combinations thereof, more preferably an aluminum salt, even more preferably at least one salt comprising at least one of aluminum nitrate (Al(NO₃)₃), aluminum sulfate (Al₂(SO₄)₃), aluminium lactate, aluminium acetate, aluminum formate, aluminum stearate, or combinations thereof. The aqueous dispersion may comprise from about 1 to about 10 wt % of the salt, preferably from about 3 to about 8 wt % of the salt, more preferably from about 4 to about 8 wt % of the salt, by weight of the aqueous dispersion.

According to an embodiment, the aqueous dispersion comprising solid particles of a metal hydroxide composition may have a viscosity at a shear rate of 0.1 s⁻¹ of about 1,000 Pa·s or less, measured at 25° C. The aqueous dispersion may comprise particles of the metal hydroxide composition having a volume average particle size of 10 microns or smaller, as determined by X-ray diffraction or light scattering. The viscosity of the fluid may be newtonian or non-newtonian.

### Other Additives:

The aqueous dispersion comprising solid particles of a metal hydroxide composition may further comprise additional additives as are known and used in the art. For example, the aqueous dispersion may comprise one or more of wetting agents, surfactants, viscosity modifying agents, preservatives, co-solvents, stabilizers, or antimicrobial additives.

### Metal Hydroxide Composition:

According to certain embodiments, the metal hydroxide composition comprises at least one of Group 3A hydroxides, Group 4 hydroxides, or combinations thereof; preferably titanium hydroxide(s), zirconium hydroxide(s), aluminum hydroxide(s), αAlO(OH), γAlO(OH), 5Al₂O₃·H₂O, or combinations thereof, and more preferably γAlO(OH). After the metal hydroxide composition is applied to the hot surface of the glass substrate, the hot end coating thus formed comprises oxide(s) of the metal(s); said oxide(s) of the metal(s) comprising at least one of Group 3A oxides, Group 4A oxides, or combinations thereof, preferably AlₓO_{y} (0<x≤2 and 0<y≤3), TiO₂, TiO, Ti₂O₃Ti_{z}Oₐ (0<z≤2 and 0<a≤3), ZrO₂, Zr_{b}O_{c} (0<b≤1 and 0<c≤2) Al₂O₃, Al₂O, AlO, AlO, AlₓO_{y} (0<x≤2 and 0<y≤3) or combinations thereof; more preferably Al₂O₃, Al₂O, AlO, AlₓO_{y} (0<x≤2 and 0<y≤3) or combinations thereof.

The solid particles of the metal hydroxide composition may have a BET surface area of from 50 to 300 m²/g, or from 75 to 200 m²/g as measured using nitrogen adsorption. The solid particles of the metal hydroxide composition may have a crystallite size (120 plane) from 50 to 5000 Å or from 50 to 1000 Å, measured using X-ray diffraction. The solid particles of the metal hydroxide composition may have a porosity of less than 1 ml/gm, preferably from 0.3 to 0.9 ml/g, measured using nitrogen desorption.

### Hot End Coating:

After application to the hot surface of the glass substrate, the coating (“hot end” coating) thus formed comprise(s) oxide(s) of the metal. These metal oxide(s) comprise at least one of Group 3A oxides, Group 4A oxides, or combinations thereof; preferably AlₓO_{y} (0<x≤2 and 0<y≤3), TiO₂, TiO, Ti₂O₃, Ti_{z}Oₐ (0<z≤2 and 0<a≤3), ZrO₂, Zr_{b}O_{c} (0<b≤1 and 0<c≤2) Al₂O₃, Al₂O, AlO, AlₓO_{y} (0<x≤2 and 0<y≤3) or combinations thereof; more preferably Al₂O₃, Al₂O, AlO, AlₓO_{y} (0<x≤2 and 0<y≤3) or combinations thereof.

The coating may be an inorganic coating. According to certain embodiments, the coating formed from the aqueous dispersion of the metal hydroxide is substantially free of halides, preferably substantially free of Cl. Substantially free of halide means less than 10% by weight, or less than 5%, or 1% by weight or less, or 5000 ppm or less, or 1000 ppm or less, or 500 ppm or less, or 100 ppm or less or 50 ppm or less, or 10 ppm or less of halide, based on the weight of the hot end coating.

According to an embodiment, the coating is substantially free of carbon. Substantially free of carbon means less than 10% by weight of carbon, or less than 5% by weight, or 1% by weight or less of carbon, or 5000 ppm or less, or 1000 ppm or less, or 500 ppm or less, or 100 ppm or less or 50 ppm or less, or 10 ppm or less of carbon based on the weight of the hot end coating.

According to certain embodiments, the hot end coating may be substantially free of metals other than aluminum. Substantially free of metals other than aluminum means less than 1% by weight, or less than 5000 ppm, or less than 1000 ppm, or less than 500 ppm other than aluminum, based on the weight of the hot end coating.

According to an embodiment, the coating comprises at least one of AlₓO_{y} (0<x≤2 and 0<y≤3), Al₂O₃, Al₂O, AlO, AlₓO_{y} (0<x≤2 and 0<y≤3) or combinations thereof; more preferably Al₂O₃, Al₂O, AlO, AlₓO_{y} (0<x≤2 and 0<y≤3), or combinations thereof; and the coating is substantially free of metals other than aluminum, halogens, and carbon.

According to an embodiment, the volume average particle size of the metal oxide(s) in the hot end coating may be 50 microns or smaller. According to another embodiment, the volume average particle size or may be from about 1 nm to about 50 microns, or preferably about 10 nm to about 10 microns, as determined by Scanning Electron Microscopy or by X-ray diffraction or light scattering.

According to an embodiment, the resulting coating comprising the metal oxide(s) is substantially transparent, colorless, and/or without iridescence to the naked eye. Transparent is defined herein as capable of transmitting light such that the unaided human eye may see through it. Iridescence as defined herein means having a rainbow effect or appearance of the coating as observable by the unaided human eye. Colorless as defined herein means no color is discernable to the unaided human eye. According to an embodiment, the resulting hot end coating comprising the metal oxide(s) is homogeneous. Homogeneous as defined herein means that the hot end coating and/or the metal oxide(s) comprising the hot end coating have a uniform appearance as viewed by the naked eye. According to an embodiment, upon and/or after application of the aqueous dispersion to the hot glass substrate, the hot end coating forms a film which may or may not be continuous.

According to an embodiment, a cold end coating may adhere to the hot end coating comprising the metal oxide(s).

According to an embodiment, the coated glass article comprises at least one of a hollow glass container, bottle, or flat glass

### Emissions During the Coating Process:

According to an embodiment, the coating process results in the release of (emissions of) essentially only water. “Essentially only water” as used herein means that the coating process results in emissions of halogens and/or carbons that are <10%, or <5%, <3%, <2%, <1%, <0.5% by weight of the aqueous dispersion composition that is applied to the hot surface of the glass substrate to produce the metal(s) oxide hot end coating on the surface of the glass substrate.

### Coated Glass Article:

A coated glass substrate produced by the method disclosed herein is provided. The coated glass article comprises:
a glass substrate and
a hot end coating on the glass substrate,
the hot end coating comprises at least one of Group 3A oxides, Group 4A oxides, or combinations thereof; preferably TiO₂, TiO, Ti₂O₃, Ti_{z}Oₐ (0<z≤2 and 0<a≤3), ZrO₂, Zr_{b}O_{c} (0<b≤1 and 0<c≤2), Al₂O₃, Al₂O, AlO, AlₓO_{y} (0<x≤2 and 0<y≤3) or combinations thereof, more preferably Al₂O₃, Al₂O, AlO, AlₓO_{y} (0<x≤2 and 0<y≤3) or combinations thereof.

According to an embodiment, the hot end coating is substantially free of halides, preferably substantially free of Cl. As used herein, substantially free of means less than 1% by weight of halide, or less than 5000 ppm, or less than 1000 ppm, or less than 500 ppm, or less than 100 ppm, or less than 50 ppm, or less than 10 ppm, of halide, based on the weight of the hot end coating. According to an embodiment, deionized water may be used to form the aqueous dispersion. According to an embodiment, tap water may used to form the aqueous dispersion. According to an embodiment, the hot end coating is substantially free of carbon. Substantially free of carbon means less than 1% by weight of carbon, or less than 5000 ppm, or less than 1000 ppm, or less than 500 ppm, or less than 100 ppm of carbon, based on the weight of the hot end coating. According to certain embodiments, the hot end coating may be substantially free of metals other than aluminum. Substantially free of means less than 1% by weight of metal other than aluminum, or less than 5000 ppm, or less than 1000 ppm, or less than 500 ppm, of metal other than aluminum, by weight of the hot end coating.

According to an embodiment, the hot end coating comprises at least one of AlₓO_{y} (0<x≤2 and 0<y≤3), Al₂O₃, Al₂O, AlO, AlₓO_{y} (0<x≤2 and 0<y≤3) or combinations thereof; more preferably Al₂O₃, Al₂O, AlO, AlₓO_{y} (0<x≤2 and 0<y≤3) or combinations thereof; and the coating is substantially free of metals other than aluminum. Substantially free of means less than 1% by weight, or less than 5000 ppm, or less than 1000 ppm, or less than 500 ppm, of metal other than aluminum by weight of the hot end coating.

According to an embodiment, the coated glass article further comprises a cold end coating on the hot end coating. According to an embodiment, the coated glass article comprises at least one of a hollow glass container, bottle, or flat glass.

Exemplary aspects of the invention may be summarized as follows.

Aspect 1: A method of coating a glass substrate with a hot end coating, comprising:
a) applying an aqueous dispersion comprising particles of a metal hydroxide composition onto a surface of the glass substrate, the surface having a temperature of from about 450° C. to about 800° C., thereby forming the hot end coating on the glass substrate;
wherein after application the hot end coating comprises oxide(s) of the metal, or combinations thereof.

Aspect 2. The method of Aspect 1, wherein emissions resulting from the method of Aspect 1 comprise essentially only water and are substantially free of halogen and/or carbon.

Aspect 3: The method of Aspect 1 or Aspect 2, wherein the metal hydroxide composition comprises at least one of Group 3A hydroxides, Group 4 hydroxides, or combinations thereof; preferably titanium hydroxide(s), zirconium hydroxide(s), aluminum hydroxide(s), αAlO(OH), γAlO(OH), 5Al₂O₃·H₂O, or combinations thereof; more preferably γAlO(OH); and/or wherein after application the coating comprises oxide(s) of the metal comprising at least one of Group 3A oxides, Group 4A oxides, or combinations thereof; preferably AlₓO_{y} (0<x≤2 and 0<y≤3), TiO₂, TiO, Ti₂O₃, Ti_{z}Oₐ (0<z≤2 and 0<a≤3), ZrO₂, Zr_{b}O_{c} (0<b≤1 and 0<c≤2), Al₂O₃, Al₂O, AlO, AlₓO_{y} (0<x≤2 and 0<y≤3) or combinations thereof; more preferably Al₂O₃, Al₂O, AlO, AlₓO_{y} (0<x≤2 and 0<y≤3) or combinations thereof.

Aspect 4: The method of any of Aspects 1-3, wherein the aqueous dispersion has a pH less than 8, preferably from about 1 to about 7, more preferably from about 2 to about 7, most preferably from about 3 to about 7.

Aspect 5: The method of any of Aspects 1-4, wherein the aqueous dispersion further comprises at least one or more acids or combination thereof; preferably nitric acid, formic acid, hydrochloric acid, sulfuric acid, phosphoric acid, hydrobromic acid, or combinations thereof; more preferably nitric acid, formic acid, or a combination thereof; most preferably nitric acid.

Aspect 6: The method of any of Aspects 1-5, wherein the aqueous dispersion comprises about 1 to about 70 wt %, more preferably about 5 to about 70 wt %, most preferably about 10 to about 70 wt %, of the solid particles of the metal hydroxide composition by weight of the aqueous dispersion.

Aspect 7: The method of any of Aspects 1-6, wherein the aqueous dispersion further comprises at least one salt, the at least one salt preferably comprising at least one of Group 3A or Group 4 elements, preferably an aluminum salt, more preferably at least one salt comprising at least one of aluminum nitrate Al(NO₃)₃, aluminum sulfate (Al₂ (SO₄)₃), aluminum lactate, aluminium acetate, aluminum formate, aluminum stearate, or combinations thereof.

Aspect 8: The method of any of Aspects 1-7, further comprising
b) optionally cooling the glass substrate and the hot end coating to a temperature of from about 80° C. to about 350° C., preferably from about 100° C. to about 250° C., more preferably from about 100° C. to about 200° C.; and
c) applying a cold end coating onto the hot end coating that adheres to the coated glass surface.

Aspect 9: The method of any of Aspects 1-8, wherein the aqueous dispersion is applied by spraying, optionally at a pressure of the aqueous dispersion from about 2 to about 100 psi, preferably at a pressure from about 2 to about 70 psi.

Aspect 10: The method of any of Aspects 1-9 where the spraying is applied by a sprayer which is hydraulic, pneumatic and/or mechanical or a combination thereof, preferably at least one of air sprayer, ultrasonic atomizer, rotary atomizer, airless atomizer, and electrostatic atomizer.

Aspect 11: The method of any of Aspects 1-10, wherein the hot end coating is substantially free of halides, preferably substantially free of Cl.

Aspect 12: The method of any of Aspects 1-11, wherein the hot end coating is substantially free of carbon.

Aspect 13: The method of any of Aspects 1-12 wherein said method is performed in air at atmospheric pressure.

Aspect 14: The method of any of Aspects 1-13, wherein the hot end coating comprises at least one of AlₓO_{y} (0<x≤2 and 0<y≤3), Al₂O₃, Al₂O, AlO, AlₓO_{y} (0<x≤2 and 0<y≤3) or combinations thereof; more preferably Al₂O₃, Al₂O, AlO, AlₓO_{y} (0<x≤2 and 0<y≤3) or combinations thereof; and wherein said hot end coating is substantially free of metals other than aluminum.

Aspect 15: The method of any of Aspects 1-14, wherein the hot end coating is substantially transparent, colorless, and/or without iridescence to the naked eye.

Aspect 16: The method of any of Aspects 1-15 wherein said aqueous dispersion comprising solid particles of a metal hydroxide composition has viscosity of 1,000 Pa·s at a shear rate of 0.1 s⁻¹ or less, measured at 25° C. and the particles have a volume average particle size of 100 microns or smaller, preferably 1 nm to 10 microns as determined by X-ray diffraction or light scattering.

Aspect 17: The method of any of Aspects 1-16 wherein the hot end coating is homogeneous.

Aspect 18: The method of any of Aspects 1-17 wherein the aqueous dispersion comprising solid particles of a metal hydroxide composition further comprises at least one of wetting agents, surfactants, viscosity modifying agents, preservatives, stabilizers, antimicrobial additives, or combinations thereof.

Aspect 19: A coated glass substrate produced by the method of any of Aspects 1-18.

Aspect 20: A coated glass article comprising:
a glass substrate and
a hot end coating on the glass substrate;
the hot end coating comprising at least one of Group 3A oxides, Group 4A oxides, or combinations thereof; preferably TiO₂, TiO, Ti₂O₃, Ti_{z}Oₐ (0<z≤2 and 0<a≤3), ZrO₂, Zr_{b}O_{c} (0<b≤1 and 0<c≤2), Al₂O₃, Al₂O, AlO, AlₓO_{y} (0<x≤2 and 0<y≤3) or combinations thereof; more preferably Al₂O₃, Al₂O, AlO, AlₓO_{y} (0<x≤2 and 0<y≤3) or combinations thereof.

Aspect 21: The coated glass article of Aspect 20, wherein the hot end coating is substantially free of halides, preferably substantially free of Cl, and substantially free of carbon.

Aspect 22: The coated glass article of any of Aspects 20-21, wherein the coated glass article comprises at least one of a hollow glass container, or flat glass.

Within this specification, embodiments have been described in a way which enables a clear and concise specification to be written, but it is intended and will be appreciated that embodiments may be variously combined or separated without departing from the invention. For example, it will be appreciated that all preferred features described herein are applicable to all aspects of the invention described herein.

In some embodiments, the invention herein can be construed as excluding any element or process step that does not materially affect the basic and novel characteristics of the compositions, methods for making the compositions, methods for using the compositions, and articles prepared from the compositions. Additionally, in some embodiments, the invention can be construed as excluding any element or process step not specified herein.

Although the invention is illustrated and described herein with reference to specific embodiments, the invention is not intended to be limited to the details shown. Rather, various modifications may be made in the details within the scope and range of equivalents of the claims and without departing from the invention.

### EXAMPLES

### Methods:

Temperatures of the glass substrate were measured by a pyrometer (emissivity of the coated soda lime glass surfaces was 0.95).

Viscosity of the dispersions was measured using an Anton Paar MCR (modular compact rheometer) 502 stress control rheometer over a range of low shear rate (0.1-10 s⁻¹). The measurement was made using a double wall couette, where there are two gaps, one between the outer wall of the cup and the outer circumference of the rotor, and another between the inside wall of the cup and the interior circumference of the rotor (outer gap is 0.918 mm and the interior gap is 0.837 mm).

The volumetric average particle sizes of the particles in the aqueous dispersions was measured by X-ray diffraction technique using a Rigaku SmartLab diffractometer in transmission mode with the capillary holder instrument model. The data was analyzed using NANO solver software version 3 and light scattering measurements were obtained using a Mastersizer 3000, Malvern. As is known in the art, x-ray diffraction is used to measure volume average particle size of about 300 nm and smaller. Light scattering is used to measure volumetric average particle sizes of about 100 nm and larger.

The Scanning Electron Microscopy was performed using a Hitachi SU 8010 instrument.

First, aqueous dispersions of oxyhydroxide (hydroxide) were prepared. Alumina hydrate (aluminum hydroxide also referred to as aluminum oxyhydroxide) Dispal® powders from Sasol Chemical were used to form aqueous dispersions. The volume average particle size of the particles in the dispersion was 18 nm. The aqueous dispersion was then sprayed onto a soda lime glass surface at a temperature above 400° C. The temperature of the soda lime glass when the aqueous dispersions were sprayed was 530-540° C. The viscosities of the aqueous dispersion as measured at a shear rate of 0.1 s⁻¹ were: 10 wt % dispersion:viscosity=4.3×10⁻³ Pa·s; 30 wt % dispersion:viscosity=20 Pa·s.

The dispersion of aluminum oxyhydroxide was prepared by slowly adding Dispal® powder to deionized water to prepare aqueous dispersions including from 5 to 35 wt % of aluminum oxyhydroxide by weight of the aqueous dispersions. During preparation, the dispersions were continuously mixed even after the powder had been completely dispersed in the water. A clean piece of soda lime glass was annealed on a hot plate to a temperature higher than 400° C., as measured using a pyrometer. When the glass temperature had reached 400° C. or higher, the hot glass surface was sprayed with the prepared aqueous dispersion using an air brush (Grex, model Tritium), equipped with a crown nozzle. The air pressure in the air brush was varied between 10 and 40 psi, depending on the concentration of the aqueous dispersion. Higher pressures were used for the more concentrated dispersions. After the aqueous dispersion was applied, the glass substrate and its hot end coating were allowed to cool down until it reached 125° C. The coatings were transparent and lacked iridescence. The volume average particle size of the metal oxide layer that comprised the hot end coating was less than 200 nm as measured using scanning electron microscopy. When the glass substrate and its hot end coating reached 125° C., a wax emulsion cold end coating (Tegoglas® RP-40, Arkema) was sprayed onto the hot end coating using the same airbrush at an air pressure of 15 psi with the nozzle fully opened.

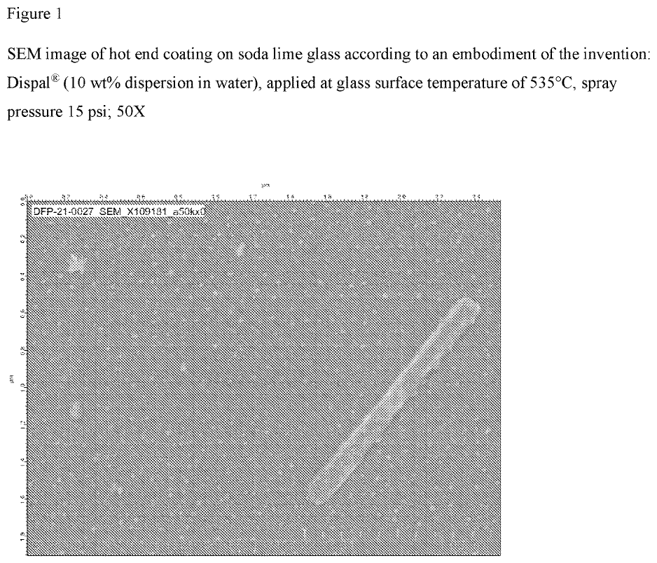

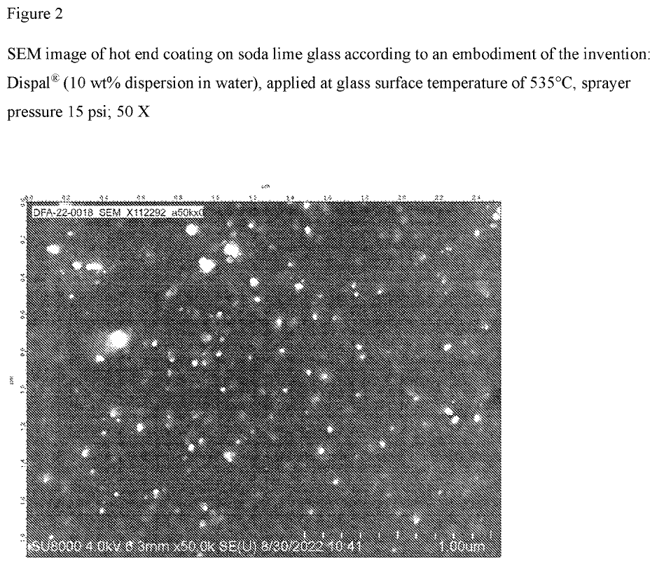

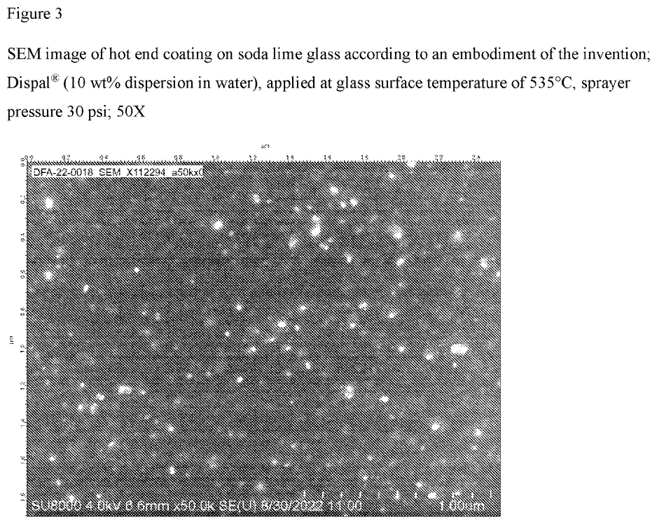

SEM images of the metal oxide coating are shown in FIGS. 1-3. As can been seen in the images, the metal oxide coating in in the form of “islands” substantially uniformly distributed on the surface of the soda lime glass substrate. The composition of each of these islands may be substantially homogeneous or not. The volume average particle size of these islands is reported above as the volume average particle size of the metal oxide layer. The metal oxide coating may form a film which may be continuous.

1. A method of coating a glass substrate with a hot end coating, comprising:
a) applying an aqueous dispersion comprising particles of a metal hydroxide composition onto a surface of the glass substrate, the surface having a temperature of from about 450° C. to about 800° C., thereby forming the hot end coating on the glass substrate;
wherein after application the hot end coating comprises oxide(s) of the metal, or combinations thereof.

2. The method of claim 1, wherein emissions resulting from the method comprise only water and are substantially free of halogen and/or carbon.

3. The method of claim 1, wherein the metal hydroxide composition comprises at least one of Group 3A hydroxides, Group 4 hydroxides, or combinations thereof; and/or wherein after application the coating comprises oxide(s) of the metal comprising at least one of Group 3A oxides, Group 4A oxides, or combinations thereof.

4. The method of claim 1, wherein the aqueous dispersion has a pH less than 8.

5. The method of claim 1, wherein the aqueous dispersion further comprises at least one or more acids or combination thereof.

6. The method of claim 1, wherein the aqueous dispersion comprises about 1 to about 70 wt % of the solid particles of the metal hydroxide composition by weight of the aqueous dispersion.

7. The method of claim 1, wherein the aqueous dispersion further comprises at least one salt, and wherein the at least one salt comprises at least one of Group 3A or Group 4 elements or combinations thereof.

8. The method of claim 1, further comprising
b) optionally cooling the glass substrate and the hot end coating to a temperature of from about 80° C. to about 350° C.; and
c) applying a cold end coating onto the hot end coating that adheres to the coated glass surface.

9. The method of claim 1, wherein the aqueous dispersion is applied by spraying, optionally at a pressure of the aqueous dispersion from about 2 to about 100 psi.

10. The method of claim 1, wherein the spraying is applied by a sprayer which is hydraulic, pneumatic and/or mechanical or a combination thereof.

11. The method of claim 1, wherein the hot end coating is substantially free of halides and/or carbon.

12. (canceled)

13. The method of claim 1, wherein said method is performed in air at atmospheric pressure.

14. The method of claim 1, wherein the hot end coating comprises at least one of AlₓO_{y} (0<x≤2 and 0<y≤3), Al₂O₃, Al₂O, AlO, AlₓO_{y} (0<x≤2 and 0<y≤3) or combinations thereof; and wherein said hot end coating is substantially free of metals other than aluminum.

15. The method of claim 1, wherein the hot end coating is substantially transparent, colorless, and/or without iridescence to the naked eye

16. The method of claim 1, wherein said aqueous dispersion comprising solid particles of a metal hydroxide composition has viscosity of 1,000 Pa·s at a shear rate of 0.1 s⁻¹ or less, measured at 25° C., and the particles have a volume average particle size of 100 microns or smaller as determined by X-ray diffraction or light scattering.

17. The method of claim 1, wherein the hot end coating is homogeneous.

18. A coated glass substrate produced by the method of claim 1.

19. A coated glass article comprising:
a glass substrate, and
a hot end coating on the glass substrate;
the hot end coating comprising at least one of Group 3A oxides, Group 4A oxides, or combinations thereof.

20. The coated glass article of claim 19, wherein the hot end coating is substantially free of halides and/or carbon.

21. The coated glass article of claim 1, wherein the coated glass article is a hollow glass container or flat glass.

22. The method of claim 3, wherein the metal hydroxide composition comprises at least one of titanium hydroxide(s), zirconium hydroxide(s), aluminum hydroxide(s), αAlO(OH), γAlO(OH), 5Al₂O₃·H₂O, or combinations thereof; and/or wherein after application the coating comprises at least one of AlₓO_{y} (0<x≤2 and 0<y≤3), TiO₂, TiO, Ti₂O₃, Ti_{z}Oₐ (0<z≤2 and 0<a≤3), ZrO₂, Zr_{b}O_{c} (0<b≤1 and 0<c≤2), Al₂O₃, Al₂O, AlO, AlₓO_{y} (0<x≤2 and 0<y≤3) or combinations thereof.

23. The coated glass article of claim 19, wherein the hot end coating comprising at least one of TiO₂, TiO, Ti₂O₃, Ti_{z}Oₐ (0<z≤2 and 0<a≤3), ZrO₂, Zr_{b}O_{c} (0<b≤1 and 0<c≤2), Al₂O₃, Al₂O, AlO, AlₓO_{y} (0<x≤2 and 0<y≤3) or combinations thereof.
